(19) United States
(12) Patent Application Publication
(10) Pub. No.: US 2025/0254912 A1
(43) Pub. Date: Aug. 7, 2025

(54) SEMICONDUCTOR DEVICE WITH DIELECTRIC ON EPITAXY SIDEWALL

(71) Applicant: TAIWAN SEMICONDUCTOR MANUFACTURING COMPANY, LTD., Hsinchu (TW)

(72) Inventors: Shih-Cheng CHEN, New Taipei City (TW); Wen-Ting LAN, Hsinchu City (TW); Jung-Hung CHANG, Changhua County (TW); Tsung-Han CHUANG, Tainan City (TW); Chia-Cheng TSAI, Hsinchu City (TW); Kuo-Cheng CHIANG, Hsinchu County (TW)

(73) Assignee: TAIWAN SEMICONDUCTOR MANUFACTURING COMPANY, LTD., Hsinchu (TW)

(21) Appl. No.: 18/435,180

(22) Filed: Feb. 7, 2024

(51) Int. Cl. H01L 29/786; H01L 29/08; H01L 29/66; H01L 29/775; H01L 29/78

(52) U.S. Cl. CPC H10D 30/6706; H10D 30/014; H10D 30/031; H10D 30/43; H10D 30/6757; H10D 30/797; H10D 62/151; H10D 64/015; H10D 64/018

(57) ABSTRACT

A method includes following steps. A semiconductor fin is formed on a substrate. A source/drain recess is formed in the semiconductor fin. A first isolation sidewall dielectric and a second isolation sidewall dielectric are formed lining opposite sidewalls of the source/drain recess. An epitaxial layer is formed in the source/drain recess. The epitaxial layer is recessed such that a top surface of the epitaxial layer is lower than top surfaces of the first and second isolation sidewall dielectrics. An epitaxial source/drain region is formed on the recessed epitaxial layer. A gate structure is formed adjacent the epitaxial source/drain region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 20 are cross-sectional views of intermediate stages in the manufacturing of GAA-FETs, in accordance with some embodiments.

FIG. 21 illustrates an enlarged of a source/drain region illustrated in FIG. 20.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit (IC) structures and methods of forming the same, and more particularly to fabricating gate-all-around (GAA) transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

As scales of the fin width in fin field effect transistors (FinFET) decreases, channel width variations might cause mobility loss. GAA transistors, such as nanosheet transistors are being studied as an alternative to fin field effect transistors. In a nanosheet transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents.

The present disclosure, in various embodiments, provides an improved GAA device structure, focusing on balancing direct current (DC) and alternating current (AC) performance of GAA devices. In particular, embodiments of the present disclosure involve enlarging the volume of a high germanium (Ge) concentration epitaxial layer (also called “L2” layer) through recessing an underlying epitaxial layer (also called “L0” layer). This modification enhances the stress effect and hence carrier mobility, which in turn improves DC performance. However, it also leads to increased off-state current (Iboff) and gate capacitance (Cgc), which in turn lead to slower switching speeds, thus negatively impacting AC performance. To address this issue, a sidewall dielectric is formed on sidewall of the L0 layer. This dielectric acts as an insulator, isolating the source/drain epitaxial regions and the substrate, which in turn effectively counters some of the unwanted increases in Iboff and Cgc resulting from the recessing step performed on the L0 layer. As a result, the AC performance of the transistor, which was at risk of degradation due to the L0 recess step, can be improved by the introduction of the sidewall dielectric.

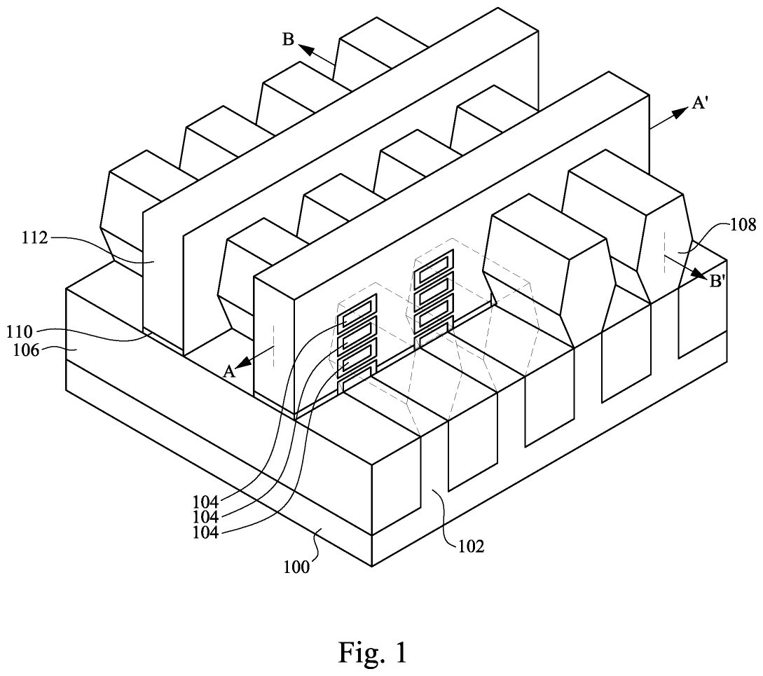

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. The isolation regions 106 are formed in trenches between the fins 102 and thus can be interchangeably referred to as shallow trench isolation (STI) regions. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112. Source/drain region(s) may refer to a source or a drain, individually or collectively dependent upon the context.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

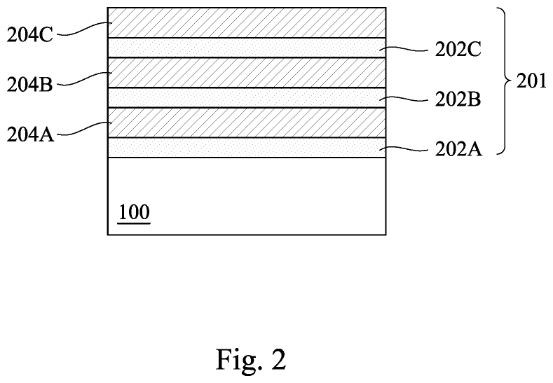

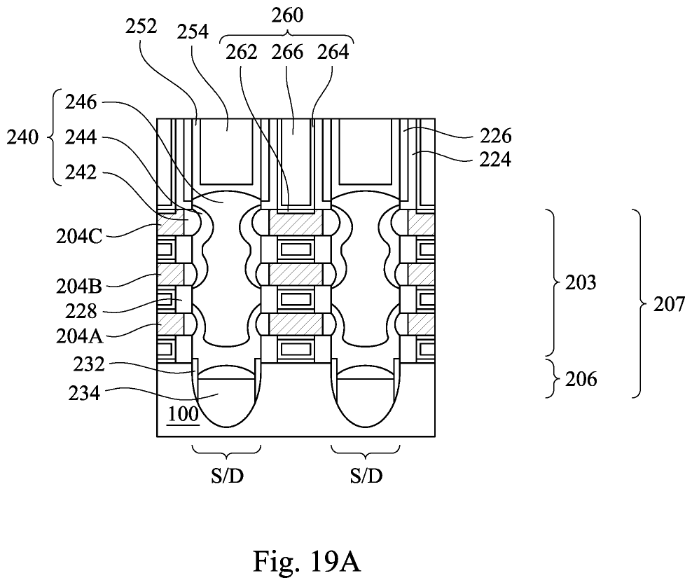

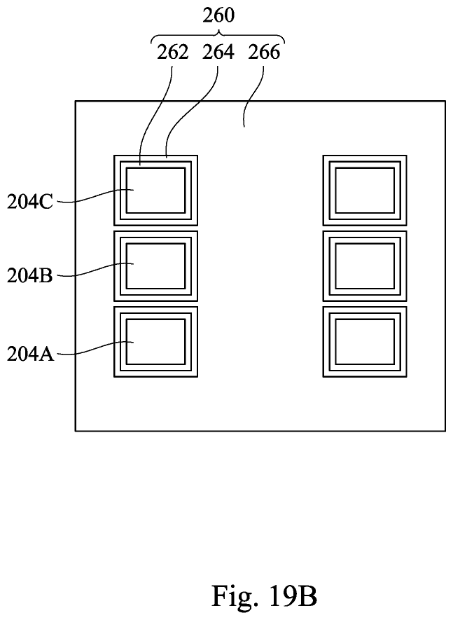

FIGS. 2 through 20 are cross-sectional views of intermediate stages in the manufacturing of GAA-FETs, in accordance with some embodiments. FIGS. 2 through 19A and 20 illustrate reference cross-section A-A′ illustrated in FIG. 1 that extends through a gate region along a longitudinal axis of the gate region. FIG. 19B illustrates reference cross-section B-B′ illustrated in FIG. 1 that extends through a fin along a longitudinal axis of the fin.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

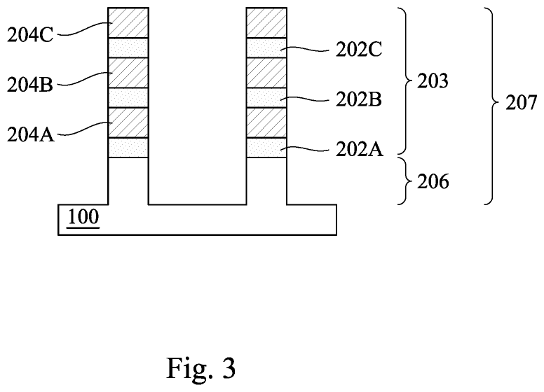

Referring now to FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and corresponding nanostructures 203 directly above the fin structure 206 can be collectively referred to as a semiconductor fin 207 extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

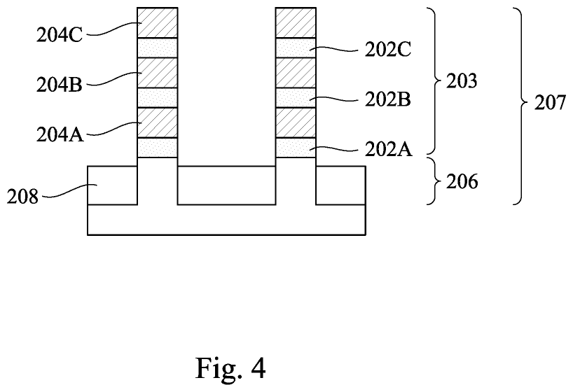

In FIG. 4, shallow trench isolation (STI) regions 208 are formed adjacent the fin structures 206. The STI regions 208 may be formed by depositing an insulation material over the substrate 100 and the semiconductor fins 207, and between adjacent semiconductor fins 207. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100 and the semiconductor fins 207. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etching the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

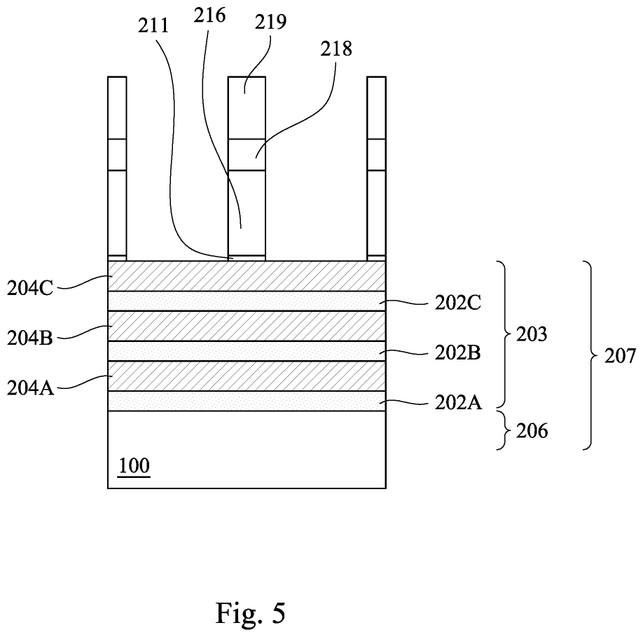

In FIG. 5, dummy gate dielectrics 211 are formed over the semiconductor fins 207, and dummy gates 216 are formed over the dummy gate dielectrics 211. In some embodiments, the dummy gates 216 have longitudinal axes perpendicular to longitudinal axes of the semiconductor fins 207. The dummy gate dielectrics 211 and the dummy gates 216 are formed by, for example, forming a blanket layer of dummy gate dielectric material over the semiconductor fins 207 and a blanket layer of dummy gate material over the layer of dummy gate dielectric material, followed by patterning the dummy gate material and the dummy gate dielectric material into the dummy gates 216 and the dummy gate dielectrics 211. In some embodiments, a patterned mask is formed over the dummy gate material for patterning the dummy gate material and the dummy gate dielectric material. The mask layer may be a dual-layer film including a bottom mask layer 218 formed over the dummy gate material and a top mask layer 219 formed over the bottom mask layer 218.

In some embodiments, materials of the dummy gate dielectrics 211 may be, for example, silicon oxide, silicon nitride, a combination thereof, or the like, and may be deposited or thermally grown according to acceptable techniques. Materials of the dummy gates 216 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The dummy gates 216 may be deposited by physical vapor deposition (PVD), CVD, sputter deposition, or other techniques for depositing the selected material. The bottom mask layer 218 and the top mask layer 219 include SiO₂, SiCN, SiON, Al₂O₃, SiN, or other suitable materials. In some embodiments, the bottom mask layer 218 and the top mask layer 219 include different materials. For example, the bottom mask layer 218 includes silicon nitride, and the top mask layer 219 includes silicon oxide.

The bottom and top mask layers 218 and 219 may be patterned using acceptable photolithography and etching techniques. The pattern of the mask layers 218 and 219 then may be transferred to the layer of dummy gate material and the layer of dummy gate material to form dummy gates 216 and dummy gate dielectrics 211, respectively. The dummy gates 216 cover respective channel regions of semiconductor fins 207. The pattern of the mask layers 218, 219 may be used to physically separate each of the dummy gates 216 from adjacent dummy gates 216. The dummy gates 216 may also have a lengthwise direction substantially perpendicular to the lengthwise direction of respective fin structures 206.

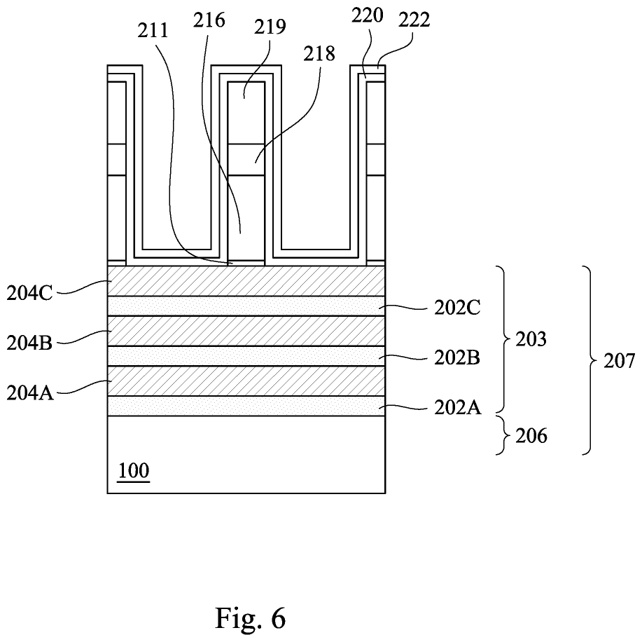

In FIG. 6, a first spacer layer 220 and a second spacer layer 222 are formed over the structures illustrated in FIG. 5 respectively. The first spacer layer 220 and the second spacer layer 222 will be subsequently patterned to act as spacers for forming self-aligned source/drain regions. In FIG. 6, the first spacer layer 220 is formed on top surfaces the semiconductor fins 207, and sidewalls of the dummy gates 216, the dummy gate dielectrics 211 and the hard mask layers 218, 219. The second spacer layer 222 is deposited over the first spacer layer 220. The first spacer layer 220 may be formed of silicon oxide, silicon nitride, silicon oxynitride (SiON), silicon oxycarbide (SiOC), silicon carbon nitride (SiCN), silicon carbon oxynitride (SiOCN), or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride (SiON), silicon oxycarbide (SiOC), silicon carbon nitride (SiCN), silicon carbon oxynitride (SiOCN), or the like, and may be deposited by CVD, ALD, or the like. In some embodiments, the first and second spacer layers 220 and 222 are both nitride-based materials but different in carbon concentration, or both carbide-based materials but different in nitrogen concentration, thereby allowing the first and second spacer layers 220 and 222 having different material properties (e.g., different etch rates).

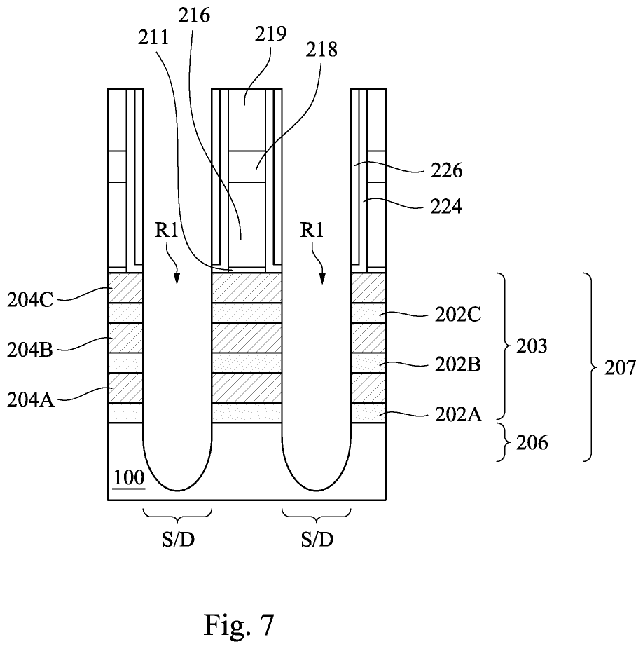

In FIG. 7, source/drain recesses R1 are formed in the semiconductor fins 207, in accordance with some embodiments. Epitaxial source/drain regions will be subsequently formed in the source/drain recesses R1. The source/drain recesses R1 may extend through the first nanostructures 202 and the second nanostructures 204, and into the substrate 100. As illustrated in FIG. 7, bottom surfaces of the source/drain recesses R1 may be lower than the top surface of the substrate 100. The source/drain recesses R1 may be formed by etching the fin structures 206, the nanostructures 203, and the substrate 100 using anisotropic etching processes, such as RIE, NBE, or the like. The anisotropic etching may be performed by a selective dry chemical etch with a plasma source and a reaction gas, serving for selectively etching first semiconductor layers 202 (e.g., SiGe) and second semiconductor layers 204 (e.g. Si) at an etch rate faster than etching the hard mask layer 219. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

Moreover, the etching process of forming source/drain recesses R1 may also etches the first spacer layer 220 and the second spacer layer 222 to form inner gate spacers 224 and outer gate spacers 226 on opposite sidewalls of the dummy gates 216. As will be discussed in greater detail below, these spacers act to self-align subsequently formed source/drain epitaxial material to source/drain regions S/D defined by the source/drain recesses R1.

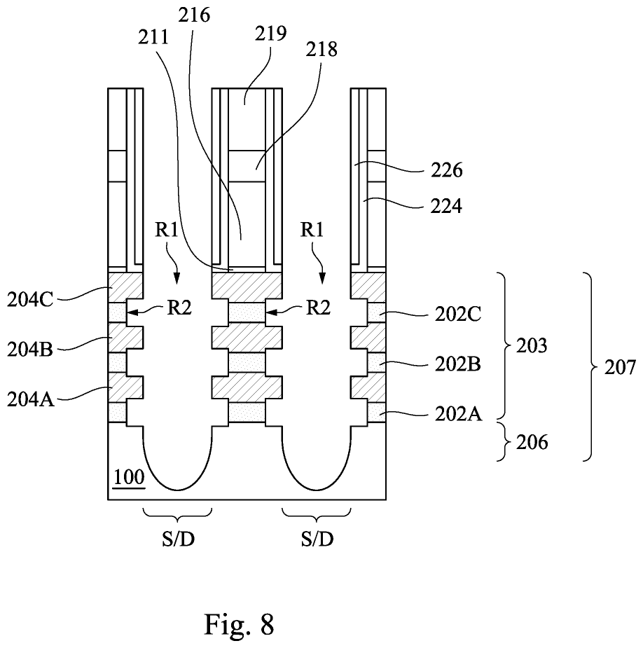

In FIG. 8, portions of sidewalls of the layers of the multi-layer stack 201 formed of the first semiconductor materials (e.g., the first nanostructures 202) exposed by the source/drain recesses R1 are etched to form sidewall recesses R2 between corresponding second nanostructures 204. Although sidewalls of the first nanostructures 202 in sidewall recesses R2 are illustrated as being straight in FIG. 8, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202. In some embodiments, as illustrated in FIG. 8, the sidewall recesses R2 also extend into corresponding second nanostructures 204. In such scenarios, the second nanostructures 204 each have a central portion and opposite peripheral portions thinner than the central portion, and the peripheral portions are exposed in the sidewall recesses R2.

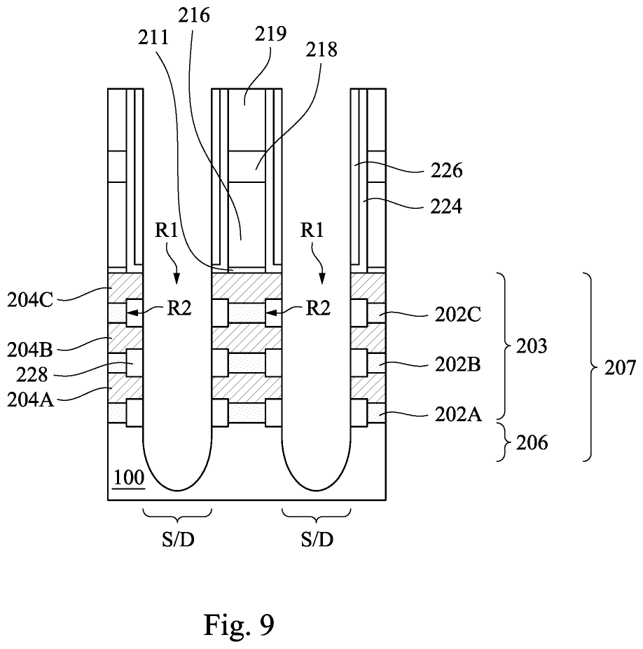

In FIG. 9, inner spacers 228 are formed in the sidewall recess R2. The inner spacers 228 may be formed by depositing an inner spacer layer (not separately illustrated) over the structures illustrated in FIG. 8. The inner spacers 228 act as isolation features between subsequently formed source/drain regions and gate structure. As will be discussed in greater detail below, source/drain epitaxial regions will be formed in the recesses source/drain recesses R1, and the first nanostructures 202 will be replaced with corresponding gate structures.

The inner spacer layer may be deposited by a conformal deposition process, such as CVD, ALD, or the like. The inner spacer layer may comprise a material such as silicon nitride, silicon oxynitride or silicon carbon oxynitride (SiOCN), although any suitable material, such as low-dielectric constant (low-k) materials having a k-value less than about 3.5, may be utilized. The inner spacer layer may then be anisotropically etched to form the inner spacers 228. Although outer sidewalls of the inner spacers 228 are illustrated as being flush with sidewalls of the second nanostructures 204, the outer sidewalls of the inner spacers 228 may extend beyond or be recessed from sidewalls of the second nanostructures 204.

Moreover, although the outer sidewalls of the inner spacers 228 are illustrated as being straight in FIG. 9, the outer sidewalls of the inner spacers 228 may be concave or convex. The inner spacer layer may be etched by an anisotropic etching process, such as RIE, NBE, or the like. The inner spacers 228 may be used to prevent damage to subsequently formed source/drain epitaxial regions by subsequent etching processes, such as etching processes used to form gate structures.

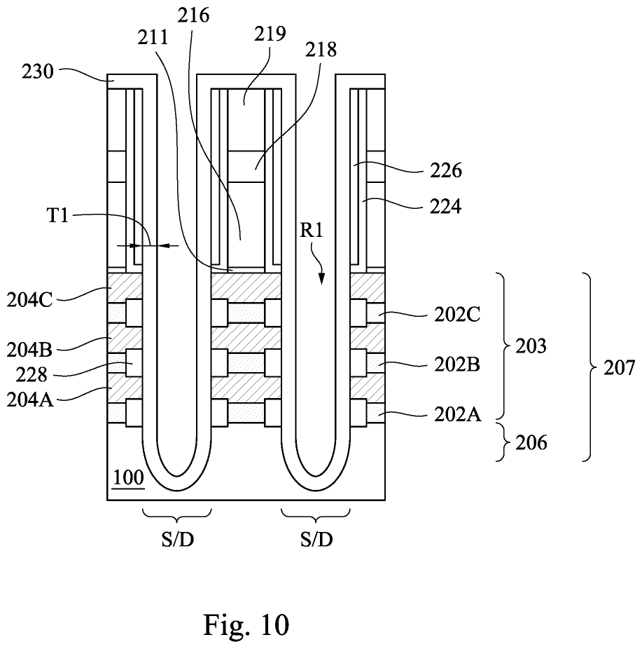

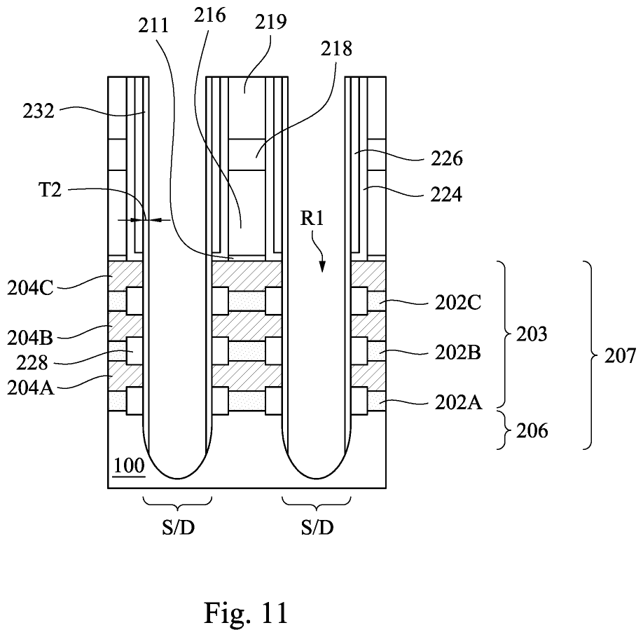

In FIG. 10, an isolation dielectric layer 230 is conformally deposited into the source/drain recessed R1 by using suitable deposition techniques, such as CVD or PVD. The composition of isolation dielectric layer 230 is primarily nitride-based, which confers enhanced durability and resistance to damage during the subsequent cleaning processes aimed at removing native oxides. For illustration, the isolation dielectric layer 230 can include nitride-based materials like silicon carbon oxynitride (SiOCN), silicon carbon nitride, or silicon oxynitride (SiON). These materials are chosen for their robustness and compatibility with the underlying semiconductor structures. An exemplary method for fabricating the isolation dielectric layer 230, especially when using silicon carbon oxynitride (SiOCN), involves plasma-enhanced chemical vapor deposition (PECVD). In this process, the semiconductor wafer, already prepared with the structure with the source/drain recesses R1 as shown in FIG. 9, is positioned in a deposition chamber. This chamber is first evacuated to create a controlled vacuum environment. Then, a mixture of precursor gases, including silane (SiH₄), ammonia (NH₄), and a carbon source such as methane (CH₄), is introduced. The process parameters, such as gas flow rates, chamber pressure, and temperature, are meticulously regulated to ensure optimal layer deposition. To initiate the deposition, radio-frequency (RF) power is applied to the chamber, generating plasma. This plasma ionizes the gas mixture, breaking down the precursors into reactive species that then chemically bond to the wafer's surface, forming the SiOCN layer. The thickness of this layer is carefully controlled by adjusting the deposition duration and other process parameters. Upon reaching the desired thickness, the gas inflow is stopped, and the wafer is allowed to cool down before being removed from the chamber. This method results in a SiOCN dielectric layer conformally deposited in the source/drain recesses R1.

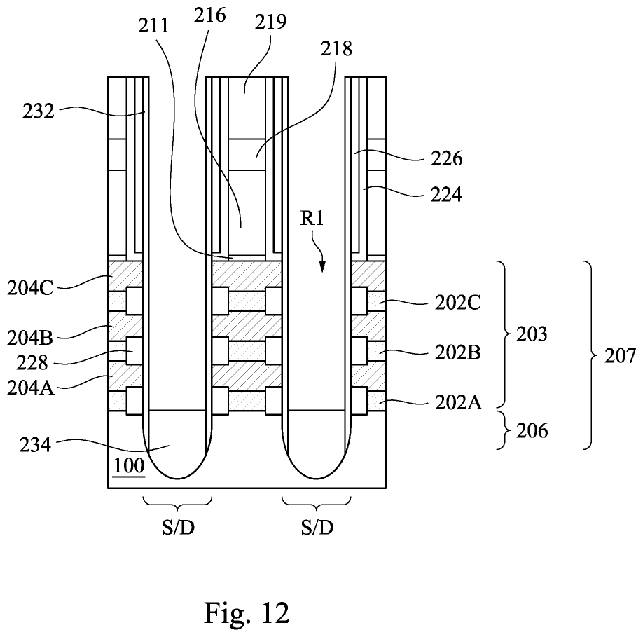

In FIG. 11, an anisotropic etching process is performed to the isolation dielectric layer 230. This process is meticulously designed to selectively remove the horizontal sections of layer 230, while preserving its vertical portions within the source/drain recesses R1. The vertical segments that remain post-etching are designated as the isolation sidewall dielectrics 232.

To exemplify the anisotropic etching of isolation dielectric layer 230, a process such as reactive ion etching (RIE) can be utilized. In this method, the semiconductor wafer with the previously deposited dielectric layer 230 (as shown in FIG. 10) is placed inside an etching chamber. The chamber is then evacuated to establish a controlled environment. A mixture of reactive gases, including fluorine-based gases or chlorine-based gases, depending on the composition of the dielectric layer 230, is introduced into the chamber. Upon initiating the etching process, radio-frequency (RF) power is applied, generating plasma from the reactive gas mixture. The energized ions in the plasma are directed towards the wafer's surface, selectively etching away the horizontal portions of the isolation dielectric layer 230 due to their orientation and exposure. The vertical parts of the isolation dielectric layer 230, protected by their positioning within the source/drain recesses R1, remain in the source/drain recesses R1.

The etching process is closely monitored and stopped at the point when the desired amount of horizontal material has been removed, leaving the vertical isolation sidewall dielectrics 232 substantially intact. However, in some embodiments, the vertical portions of the isolation dielectric layer 230 are trimmed such that the isolation sidewall dielectrics 232 have a thinner thickness than initial thickness of the isolation dielectric layer 230. For example, the isolation dielectric layer 230 has an initial thickness T1, and the isolation sidewall dielectrics 232 have a thickness T2 which is smaller than the initial thickness T1 of the isolation dielectric layer 230. In some embodiments, the etching duration is controlled such that the thickness T2 of the isolation sidewall dielectrics 232 is thick enough to mitigate the unwanted increases in Iboff and Cgc. In some embodiments, the thickness T2 of the isolation sidewall dielectrics 232 is, for example, in a range from about 1 nm to about 10 nm. If the isolation sidewall dielectrics 232 have an excessively large thickness T2 (e.g., greater than 10 nm), then the recessing amount in L0 layer is subsequent processing may be insufficient to enlarge the volume of L2 layer. If the isolation sidewall dielectrics 232 have an excessively small thickness T2 (e.g., greater than 1 nm), then the isolation sidewall dielectrics 232 may provide insufficient improvement to the off-state current (Iboff) and gate capacitance (Cgc) issues.

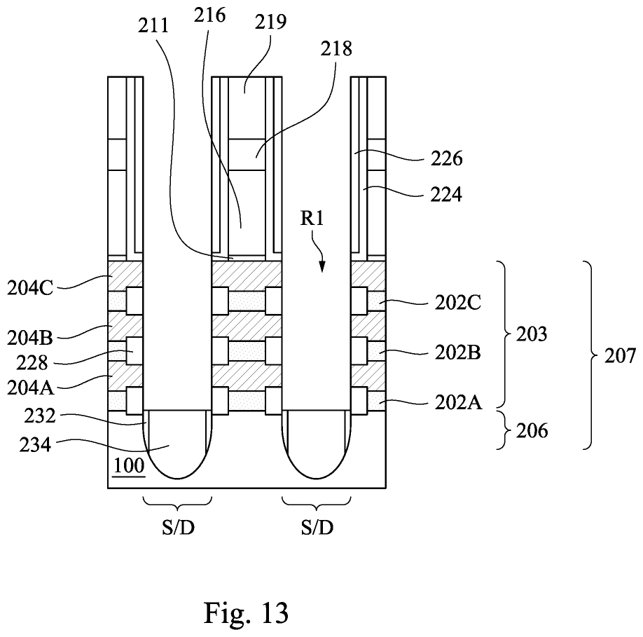

In FIG. 12, epitaxial layers 234 are formed in the source/drain recesses R1 by using a selective epitaxy growth (SEG) technique. This method allows crystalline semiconductor material selectively grown from the exposed silicon surface in bottoms of source/drain recesses R1, not from the isolation sidewall dielectrics 232. In this manner, the epitaxial layers 234 can be grown in a “bottom-up” manner, allowing the epitaxial layers 234 localized to only lower regions of the source/drain recesses R1, while leaving upper regions of the source/drain recesses R1 unfilled. In some embodiments, the epitaxial layers 234 are referred to as an “L0” layers including silicon or silicon germanium (SiGe). In some embodiments, the epitaxial layers 234 are undoped. In some embodiments, the epitaxial layers 234 are doped with a same dopant as the subsequently formed source/drain epitaxial layers.

One example of selectively growing the epitaxial layers (e.g., Si) 234 involves the use of a gas-phase chemical vapor deposition (CVD) technique. In this approach, precursor gases such as silane (SiH₄) are introduced into the reaction chamber. The substrate is heated to a temperature where these gases decompose and silicon atoms deposit selectively on the exposed silicon surfaces. This selective deposition occurs due to the differing chemical reactivity of the silicon surface at bottoms of source/drain recesses R1 compared to the isolation sidewall dielectrics 232. By controlling the temperature, gas flow rates, and pressure within the chamber, the epitaxial layers 234 can be grown with high selectivity and precision, adhering to the “bottom-up” growth pattern.

In FIG. 13, the isolation sidewall dielectrics 232 are etched back until their top surfaces are lower than the bottommost second semiconductor layer 204A. In some embodiments, this etch-back is achieved using a selective etching technique, which selectively etches the material of the isolation sidewall dielectrics 232 at a etch rate faster than that of other materials present on the substrate 100, such as the hard mask layer 219. Upon completion of this etch-back process, the top surfaces of the isolation sidewall dielectrics 232 may align with the top surfaces of the epitaxial layers 234.

In scenarios where the isolation sidewall dielectrics 232 are formed of a nitride-based material, such as silicon carbon oxynitride (SiOCN), and the epitaxial layers 234 are formed of silicon, an example of a selective etching process can be a wet etch using phosphoric acid (H₃PO₄). Phosphoric acid is effective at etching nitride-based materials at a significantly higher etch rate compared to silicon, allowing for the precise removal of the SiOCN isolation sidewall dielectrics 232 without affecting the silicon epitaxial layers 234. This selective etching ensures that the isolation sidewall dielectrics 232 are appropriately recessed while maintaining the integrity of the epitaxial layers 234.

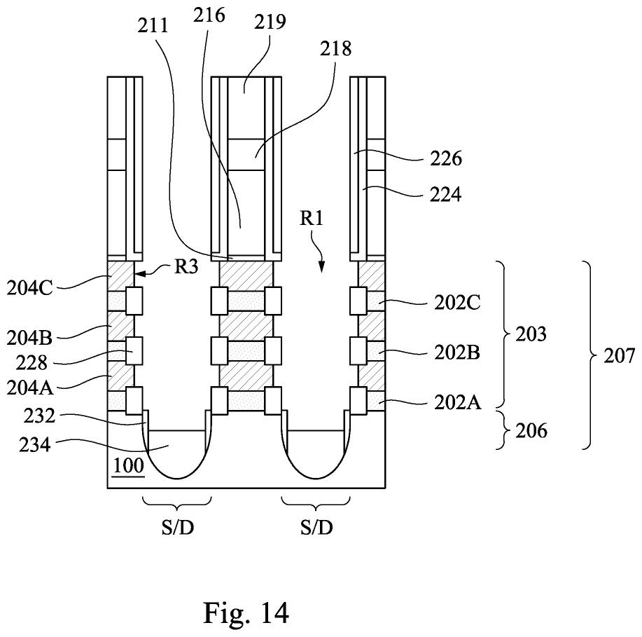

In FIG. 14, the epitaxial layers 234 are recessed in such a way that their top surfaces are positioned below the top surfaces of the isolation sidewall dielectrics 232. In certain embodiments, this recessing of the epitaxial layers 234 is achieved through a selective etching process. This process selectively etches the epitaxial layers 234 at a faster etch rate than etching the isolation sidewall dielectrics 232. Additionally, during this etching step, there may be lateral etching of the second semiconductor layers 204, leading to the formation of lateral recesses R3 on both sides of the second semiconductor layers 204. This occurs due to the material similarity between the epitaxial layers 234 and the second semiconductor layers 204, which may include, for example, silicon.

In some embodiments where the epitaxial layers 234 are silicon and the isolation sidewall dielectrics 232 are also silicon, an example of the selective etching process would be the use of a wet chemical etch employing a solution like tetramethylammonium hydroxide (TMAH). TMAH selectively etches silicon at different rates depending on the crystalline orientation, allowing for the precise removal of the epitaxial silicon layers while minimally affecting the nitride-based isolation sidewall dielectrics 232. The intact isolation sidewall dielectrics 232, post-recessing of the epitaxial layers 234, continue to serve their function effectively. In particular, the isolation sidewall dielectrics 232 isolate the subsequently formed source/drain epitaxial layers from the substrate 100. This isolation mitigates potential increases in off-state leakage current (Iboff) and gate-to-channel capacitance (Cgc), which could otherwise result from the recessing of the epitaxial layers 234.

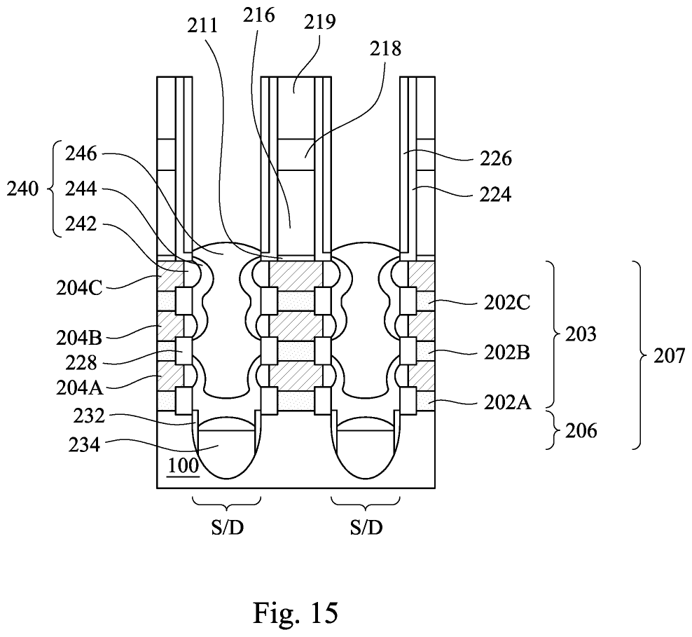

In FIG. 15, epitaxial source/drain regions 240 are formed in the source/drain recesses R1. In some embodiments, the source/drain regions 240 may exert stress on the second nanostructures 204, thereby improving device performance. As illustrated in FIG. 15, the epitaxial source/drain regions 240 are formed in the source/drain recesses R1 such that each dummy gate 216 is disposed between respective neighboring pairs of the epitaxial source/drain regions 240. In some embodiments, the gate spacers 224 and 226 are used to separate the epitaxial source/drain regions 240 from the dummy gates 216, and the inner spacers 228 are used to separate the epitaxial source/drain regions 240 from the first nanostructures 202 by an appropriate lateral distance so that the epitaxial source/drain regions 240 do not short out with subsequently formed gates of the resulting bottom GAA-FETs.

In some embodiments, the epitaxial source/drain regions 240 may include any acceptable material appropriate for p-type GAA-FETs. For example, if the second nanostructures 204 are silicon, the epitaxial source/drain regions 240 may comprise materials exerting a compressive strain on the second nanostructures 204, such as silicon germanium (SiGe), boron doped silicon germanium (SiGeB), or the like. The epitaxial source/drain regions 240 may have surfaces raised from respective upper surfaces of the nanostructures 204 and may have facets. In some embodiments, the epitaxial source/drain regions 240 may include any acceptable material appropriate for n-type GAA-FETs. For example, if the second nanostructures 204 are silicon, the epitaxial source/drain regions 240 may include materials exerting a tensile strain on the second nanostructures 204, such as silicon carbide, phosphorous doped silicon carbide, silicon phosphide, or the like.

The epitaxial source/drain regions 240 may be implanted with dopants to form source/drain regions, followed by an anneal process. The source/drain regions may have an impurity concentration of between about 1×10¹⁶ atoms/cm³ and about 1×10²³ atoms/cm³. The n-type and/or p-type impurities for source/drain regions may be any of the impurities previously discussed. In some embodiments, the epitaxial source/drain regions 240 may be in situ doped during growth. In some embodiments where the epitaxial source/drain regions 240 are doped with a p-type dopant (e.g., boron), the resulting GAA-FETs can serve as p-type transistors. In some embodiments where the epitaxial source/drain regions 240 are doped with an n-type dopant (e.g., phosphorus, arsenic, antimony), the resulting GAA-FETs can serve as n-type transistors.

The epitaxial source/drain regions 240 may comprise one or more semiconductor material layers. For example, the epitaxial source/drain regions 240 may comprise a first semiconductor material layer 242, a second semiconductor material layer 244, and a third semiconductor material layer 246. Any number of semiconductor material layers may be used for the epitaxial source/drain regions 240. Each of the first semiconductor material layer 242, the second semiconductor material layer 244, and the third semiconductor material layer 246 may be formed of different semiconductor materials and/or may be doped to different dopant concentrations. In some embodiments, the first semiconductor material layer 242, the second semiconductor material layer 244, and the third semiconductor material layer 246 have different dopant concentration (i.e., boron concentration). For example, the third semiconductor material layer 246 may have a greater boron concentration than the second semiconductor material layer 244, and the second semiconductor material layer 244 has a greater boron concentration than the first semiconductor material layer 242. In embodiments in which the epitaxial source/drain regions 240 comprise three semiconductor material layers, the first semiconductor material layer 242 may be deposited, the second semiconductor material layer 244 may be deposited over the first semiconductor material layer 242, and the third semiconductor material layer 246 may be deposited over the second semiconductor material layer 244.

In some embodiments, the first semiconductor material layer 242 is boron-doped silicon (SiB) with no or negligible germanium concentration, while the second and third semiconductor material layers 244 and 246 are boron-doped silicon germanium (SiGeB) with significantly greater germanium concentration than the first semiconductor material layer 242. In some embodiments, the third semiconductor material layer 246 may have a germanium concentration greater than the second semiconductor material layer 244. For example, the third semiconductor material layer 246 has a germanium concentration greater than about 30%, and the second semiconductor material layer 244 has a germanium concentration in a range from about 25% to about 30%. The second semiconductor layer 244 can be referred to as an “L1” layer, and the third semiconductor layer 246 can be referred to as an “L2” layer with greatest germanium concentration in the source/drain epitaxial regions 240. The L2 layer 246 is formed over the recessed L0 layer, and the L2 layer 246 with the highest germanium concentration in source/drain epitaxial region 240 can have an enlarged volume, which in turn enhances the stress effect and hence carrier mobility, thereby improving DC performance.

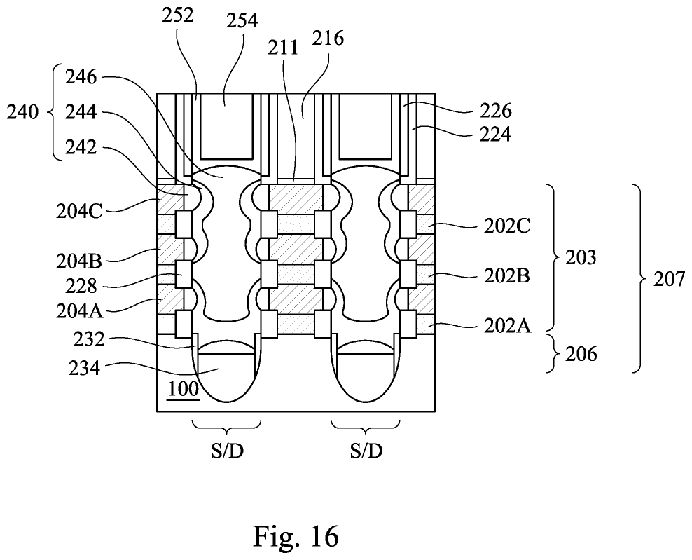

In FIG. 16 an interlayer dielectric (ILD) layer 254 is deposited over the structure illustrated in FIG. 15. The ILD layer 254 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 252 is disposed between the ILD layer 254 and the epitaxial source/drain regions 240, and the gate spacers 224, 226. The CESL 252 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 254.

After depositing the ILD layer 254 over the CESL 252, a planarization process, such as a CMP, may be performed to level the top surface of the ILD layer 254 with the top surfaces of the dummy gates 216. The planarization process may also remove the masks 218 on the dummy gates 216, and portions of the gate spacers 224, 226 along sidewalls of the masks 218. After the planarization process, top surfaces of the dummy gates 216, the gate spacers 224, 226, and the ILD layer 254 are level within process variations. Accordingly, the top surfaces of the dummy gates 216 are exposed through the ILD layer 254.

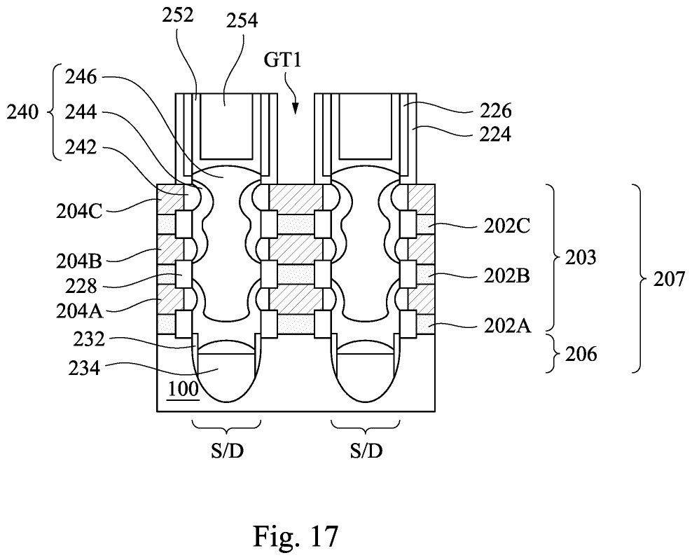

In FIG. 17, the dummy gates 216 are removed in one or more etching steps, so that gate trenches GT1 are formed between corresponding gate spacers 224. In some embodiments, portions of the dummy gate dielectrics 211 in the gate trenches GT1 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the gate spacers 224. Each gate trench GT1 exposes and/or overlies portions of nanostructures 204, which will serve as channel regions in subsequently completed GAA-FETs. The nanostructures 204 serving as the channel regions are disposed between neighboring pairs of the epitaxial source/drain regions 240. During the removal, the dummy dielectric layers 211 may be used as etch stop layers when the dummy gates 216 are etched. The dummy dielectric layers 211 may then be removed after the removal of the dummy gates 216.

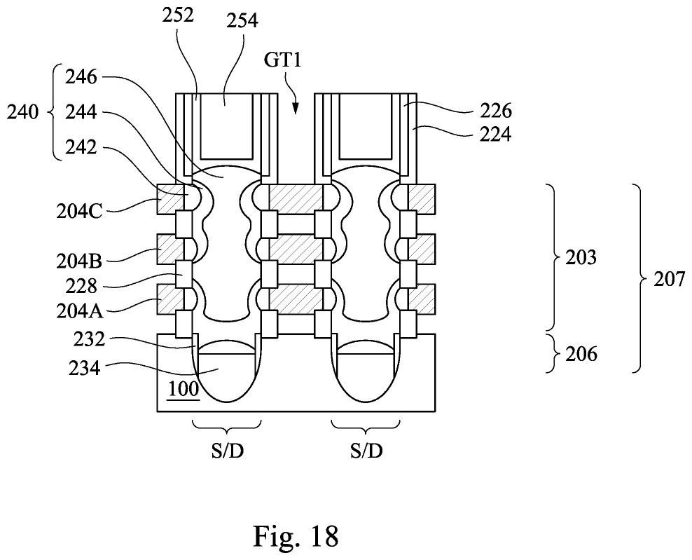

In FIG. 18, the first nanostructures 202 in the gate trenches GT1 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanosheets.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIG. 8) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

In FIGS. 19A-19B, replacement gate structures 260 are respectively formed in the gate trenches GT1 to surround each of the nanosheets 204 suspended in the gate trenches GT1. The gate structures 260 may be final gates of bottom GAA FETs. The final gate structure may be a high-k/metal gate stack, however other compositions are possible. In some embodiments, each of the gate structures 260 forms the gate associated with the multi-channels provided by the plurality of nanosheets 204. For example, high-k/metal gate structures 260 are formed within the sheet-to-sheet spaces provided by the release of nanosheets 204. In various embodiments, the high-k/metal gate structure 260 includes an interfacial layer 262 formed around the nanosheets 204, a high-k gate dielectric layer 264 formed around the interfacial layer 262, and a gate metal layer 266 formed around the high-k gate dielectric layer 264 and filling a remainder of gate trenches GT1. Formation of the high-k/metal gate structures 260 may include one or more deposition processes to form various gate materials, followed by a CMP process to remove excessive gate materials, resulting in the high-k/metal gate structures 260 having top surfaces level with a top surface of the ILD layer 254. As illustrated in the cross-sectional view of FIG. 19A, the high-k/metal gate structure 260 surrounds each of the nanosheets 204, and thus is referred to as a gate of a GAA FET.

In some embodiments, the interfacial layer 262 is semiconductor oxide (e.g., silicon oxide) formed on exposed surfaces of semiconductor materials (e.g., Si) in the gate trenches GT1 by using, for example, thermal oxidation, chemical oxidation, wet oxidation or the like. As a result, surface portions of the nanosheets 204 exposed in the gate trenches GT1 are oxidized into semiconductor oxide to form interfacial layer 262.

In some embodiments, the high-k gate dielectric layer 264 has a dielectric constant greater than a dielectric constant of SiO₂ (about 3.9). The high-k gate dielectric layer 264 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 266 includes one or more metal layers. For example, the gate metal layer 266 may include one or more work function metal layers stacked one over another and a fill metal filling up a remainder of gate trenches GT1. The one or more work function metal layers in the gate metal layer 266 provide a suitable work function for the high-k/metal gate structures 260. For a p-type GAA FET, the gate metal layer 266 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 266 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. For an n-type GAA FET, the gate metal layer 266 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials.

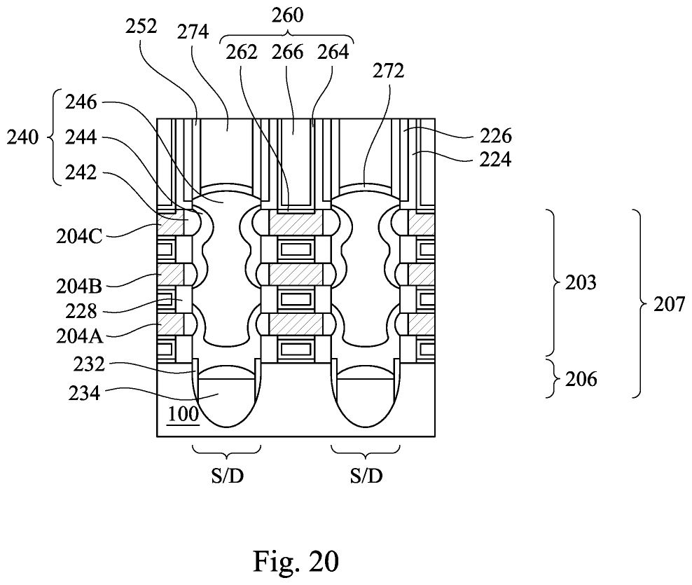

In FIG. 20, source/drain contacts 274 are formed extending through the CESL 252 and the ILD layer 254. Formation of the source/drain contacts 274 includes, by way of example and not limitation, performing one or more etching processes to form contact openings extending though the ILD layer 254 and the CESL 252 to expose the epitaxial source/drain regions 240, depositing one or more metal materials (e.g., W, Ru, Co, Cu, Ti, TiN, Ta, TaN, Mo, Ni, the like or combinations thereof) overfilling the contact openings, and then performing a CMP process to remove excessive metal materials outside the contact openings. In some embodiments, silicide regions 272 are formed on the epitaxial source/drain regions 240 before depositing metal materials of the source/drain contacts 274 into the contact openings. For example, a silicidation process may be performed on epitaxial source/drain regions 240 to reduce the contact resistance between the source/drain regions 240 and the metal contacts 274. The silicidation process may involve depositing a thin layer of a metal, such as nickel (Ni), cobalt (Co), or titanium (Ti), on the exposed surfaces of the epitaxial source/drain regions 240, followed by an annealing step, such as rapid thermal annealing (RTA), during which the metal reacts with the semiconductor materials (e.g., Si) of the source/drain regions 240 to form a metal-silicide compound (e.g., TiSi, NiSi or the like), while the metal over the dielectric materials remains unreacted. The unreacted metal can then be selectively removed using a wet or dry etching process, leaving the silicide regions 272 on the epitaxial source/drain regions 240.

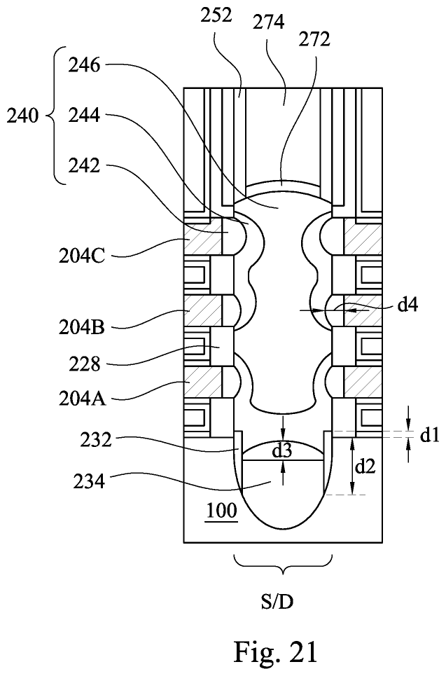

FIG. 21 illustrates an enlarged view of a source/drain region S/D illustrated in FIG. 20. As illustrated in FIG. 21, Each source/drain region includes two isolation sidewall dielectrics 232 disposed on opposite sidewalls of the epitaxial layer 234. Stated differently, each epitaxial layer 234 is disposed between two isolation sidewall dielectrics 232. Moreover, each epitaxial layer 234 has a top surface lower than top surfaces of the isolation sidewall dielectrics 232. In some embodiments, top surfaces of the isolation sidewall dielectrics 232 are higher than bottom surfaces of bottommost ones of the inner spacers 228, and bottom surfaces of the isolation sidewall dielectrics 232 are lower than the bottom surfaces of the bottommost ones of the inner spacers 228. In particular, the bottom surfaces of the isolation sidewall dielectrics 232 are lower than a top surface of the substrate 100. Moreover, the top surfaces of the isolation sidewall dielectrics 232 are lower than top surfaces of the bottommost ones of the inner spacers 228, and the isolation sidewall dielectrics 232 are in contact with the bottommost ones of the inner spacers 228.

In some embodiments, the isolation sidewall dielectrics 232 extend upwards past bottom surfaces of the bottommost inner spacers 228 by a non-zero distance d1, and the non-zero distance d1 is in a range from about 3 nm to about 8 nm. In some embodiments, the isolation sidewall dielectrics 232 extend downwards past bottom surfaces of the bottommost inner spacers 228 by a non-zero distance d2, and the non-zero distance d2 is in a range from about 5 nm to about 15 nm. In some embodiments, a portion of the first semiconductor material layer 242 grown from the epitaxial layer 234 has a thickness d3 in a range from about 1 nm to about 6 nm, and a portion of the first semiconductor material layer 242 grown from the nanostructures 204 has a thickness d4 in a range from about 1 nm to about 6 nm.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that DC performance of GAA transistors can be improved by enlarging the volume of high-germanium concentration epitaxial layer by recessing the underlying L0 epitaxial layer. Another advantage is that unwanted increases in off-state current (Iboff) and gate capacitance (Cgc) resulting from the recessing step performed on the L0 epitaxial layer can be reduced by using sidewall dielectrics formed on sidewalls of the L0 epitaxial layer, which in turn improves the AC performance of GAA transistors.

In some embodiments, a method includes forming a semiconductor fin extending from a substrate, etching a source/drain recess in the semiconductor fin, forming a first isolation sidewall dielectric and a second isolation sidewall dielectric lining opposite sidewalls of the source/drain recess, forming an epitaxial layer in the source/drain recess, recessing the epitaxial layer such that a top surface of the epitaxial layer is lower than top surfaces of the first and second isolation sidewall dielectrics, forming an epitaxial source/drain region on the recessed epitaxial layer, and forming a gate structure adjacent the epitaxial source/drain region. In some embodiments, forming the first and second isolation sidewall dielectrics comprises depositing a dielectric layer in the source/drain recess, and performing an anisotropic etching process to remove portions of the dielectric layer, while leaving vertical portions of the dielectric layer on the sidewalls of the source/drain recess. In some embodiments, the method further comprises after forming the epitaxial layer, etching the first and second isolation sidewall dielectrics such that the top surfaces of the first and second isolation sidewall dielectrics are lower than a top surface of the semiconductor fin. In some embodiments, the epitaxial layer is recessed after etching the first and second isolation sidewall dielectrics. In some embodiments, the epitaxial source/drain region comprises a first semiconductor material layer over the epitaxial layer and a second semiconductor material layer over the first semiconductor material layer. In some embodiments, the second semiconductor material layer has a germanium concentration greater than a germanium concentration of the first semiconductor material layer. In some embodiments, the second semiconductor material layer has a larger volume than the first semiconductor material layer. In some embodiments, the first semiconductor material layer and the second semiconductor material layer are boron-doped silicon germanium. In some embodiments, the top surfaces of the first and second isolation sidewall dielectrics are higher than a top surface of the substrate.

In some embodiments, a method includes forming a semiconductor fin over a substrate, the semiconductor fin comprising a plurality of first semiconductor layers alternating with a plurality of second semiconductor layers; forming a source/drain recess in the semiconductor fin; forming isolation sidewall dielectrics on opposite sidewalls of the source/drain recess; forming an epitaxial layer between the isolation sidewall dielectrics; forming an epitaxial source/drain region over the epitaxial layer; and replacing the plurality of first semiconductor layers with a gate structure. In some embodiments, the method further comprises laterally recessing the plurality of first semiconductor layers exposed in the source/drain recess, and forming inner spacers on sidewalls of the laterally recessed first semiconductor layers, respectively. Top surfaces of the isolation sidewall dielectrics are higher than bottom surfaces of bottommost ones of the inner spacers. In some embodiments, the top surfaces of the isolation sidewall dielectrics are lower than top surfaces of the bottommost ones of the inner spacers. In some embodiments, bottom surfaces of the isolation sidewall dielectrics are lower than the bottom surfaces of the bottommost ones of the inner spacers. In some embodiments, the isolation sidewall dielectrics are in contact with the bottommost ones of the inner spacers. In some embodiments, the epitaxial layer has a top surface lower than the bottom surfaces of the bottommost ones of the inner spacers. In some embodiments, the epitaxial layer has a top surface lower than top surfaces of the isolation sidewall dielectrics.

In some embodiments, a device includes a plurality of nanostructures, a gate structure, an epitaxial source/drain region, first and second isolation sidewall dielectrics, and an epitaxial layer. The nanostructures extend in a first direction above a semiconductor substrate and arranged in a second direction substantially perpendicular to the first direction. The gate structure wraps around each of the nanostructures. The epitaxial source/drain region interfaces end surfaces of the plurality of nanostructures. The first isolation sidewall dielectric and the second isolation sidewall dielectric are under the epitaxial source/drain region. The epitaxial layer is laterally between the first isolation sidewall dielectric and the second isolation sidewall dielectric. In some embodiments, the epitaxial layer has a top surface lower than top surfaces of the first and second isolation sidewall dielectrics. In some embodiments, the device further includes a plurality of inner spacers spacing apart the gate structure from the epitaxial source/drain region. The first isolation sidewall dielectric has a top surface higher than a bottom surface of a bottommost one of the inner spacers. In some embodiments, the top surface of the first isolation sidewall dielectric is lower than a top surface of the bottommost one of the inner spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor fin extending from a substrate;
etching a source/drain recess in the semiconductor fin;
forming a first isolation sidewall dielectric and a second isolation sidewall dielectric lining opposite sidewalls of the source/drain recess;
forming an epitaxial layer in the source/drain recess;
recessing the epitaxial layer such that a top surface of the epitaxial layer is lower than top surfaces of the first and second isolation sidewall dielectrics;
forming an epitaxial source/drain region on the recessed epitaxial layer; and
forming a gate structure adjacent the epitaxial source/drain region.

2. The method of claim 1, wherein forming the first and second isolation sidewall dielectrics comprises:
depositing a dielectric layer in the source/drain recess; and
performing an anisotropic etching process to remove portions of the dielectric layer, while leaving vertical portions of the dielectric layer on the sidewalls of the source/drain recess.

3. The method of claim 1, further comprising:
after forming the epitaxial layer, etching the first and second isolation sidewall dielectrics such that the top surfaces of the first and second isolation sidewall dielectrics are lower than a top surface of the semiconductor fin.

4. The method of claim 3, wherein the epitaxial layer is recessed after etching the first and second isolation sidewall dielectrics.

5. The method of claim 1, wherein the epitaxial source/drain region comprises a first semiconductor material layer over the epitaxial layer and a second semiconductor material layer over the first semiconductor material layer.

6. The method of claim 5, wherein the second semiconductor material layer has a germanium concentration greater than a germanium concentration of the first semiconductor material layer.

7. The method of claim 6, wherein the second semiconductor material layer has a larger volume than the first semiconductor material layer.

8. The method of claim 5, wherein the first semiconductor material layer and the second semiconductor material layer are boron-doped silicon germanium.

9. The method of claim 1, wherein the top surfaces of the first and second isolation sidewall dielectrics are higher than a top surface of the substrate.

10. A method comprising:
forming a semiconductor fin over a substrate, the semiconductor fin comprising a plurality of first semiconductor layers alternating with a plurality of second semiconductor layers;
forming a source/drain recess in the semiconductor fin;
forming isolation sidewall dielectrics on opposite sidewalls of the source/drain recess;
forming an epitaxial layer between the isolation sidewall dielectrics;
forming an epitaxial source/drain region over the epitaxial layer; and
replacing the plurality of first semiconductor layers with a gate structure.

11. The method of claim 10, further comprising:
laterally recessing the plurality of first semiconductor layers exposed in the source/drain recess; and
forming inner spacers on sidewalls of the laterally recessed first semiconductor layers, respectively, wherein top surfaces of the isolation sidewall dielectrics are higher than bottom surfaces of bottommost ones of the inner spacers.

12. The method of claim 11, wherein the top surfaces of the isolation sidewall dielectrics are lower than top surfaces of the bottommost ones of the inner spacers.

13. The method of claim 11, wherein bottom surfaces of the isolation sidewall dielectrics are lower than the bottom surfaces of the bottommost ones of the inner spacers.

14. The method of claim 11, wherein the isolation sidewall dielectrics are in contact with the bottommost ones of the inner spacers.

15. The method of claim 11, wherein the epitaxial layer has a top surface lower than the bottom surfaces of the bottommost ones of the inner spacers.

16. The method of claim 10, wherein the epitaxial layer has a top surface lower than top surfaces of the isolation sidewall dielectrics.

17. A device comprising:
a plurality of nanostructures extending in a first direction above a semiconductor substrate and arranged in a second direction substantially perpendicular to the first direction;
a gate structure wrapping around each of the plurality of nanostructures;
an epitaxial source/drain region interfacing end surfaces of the plurality of nanostructures;
a first isolation sidewall dielectric and a second isolation sidewall dielectric under the epitaxial source/drain region; and
an epitaxial layer laterally between the first isolation sidewall dielectric and the second isolation sidewall dielectric.

18. The device of claim 17, wherein the epitaxial layer has a top surface lower than top surfaces of the first and second isolation sidewall dielectrics.

19. The device of claim 17, further comprising:
a plurality of inner spacers spacing apart the gate structure from the epitaxial source/drain region, wherein the first isolation sidewall dielectric has a top surface higher than a bottom surface of a bottommost one of the inner spacers.

20. The device of claim 19, wherein the top surface of the first isolation sidewall dielectric is lower than a top surface of the bottommost one of the inner spacers.
